(19) United States
(12) Patent Application Publication
(10) Pub. No.: US 2019/0391458 A1
(43) Pub. Date: Dec. 26, 2019

(54) LIQUID CRYSTAL DISPLAY PANEL AND DISPLAY APPARATUS USING THE SAME

(71) Applicants: HKC Corporation Limited, Shenzhen Citym Guangdong (CN); Chongqing HKC Optoelectronics Technology Co., Limited, Chongqing (CN)

(72) Inventor: Yu-Jen CHEN, Chongqing (CN)

(21) Appl. No.: 15/561,677

(22) PCT Filed: Aug. 15, 2017
(86) PCT No.: PCT/CN2017/097482

§ 371 Date: Dec. 19, 2018

(30) Foreign Application Priority Data
Jul. 7, 2017 (CN) 201710551511.6

(51) Int. Cl. G02F 1/29; G02F 1/1368; G02F 1/1335; H01L 27/30; H01L 27/146

(52) U.S. Cl. CPC G02F 1/29; G02F 1/1368; G02F 1/133512; H01L 27/14627; H01L 27/307; H01L 27/14632; H01L 27/14612; G02F 1/133526

(57) ABSTRACT

The present invention provides a display panel and its application. The display panel comprises a first substrate, a second substrate, a liquid crystal layer disposed between the first substrate and the second substrate, an image sensing module disposed on the second substrate facing a side of the first substrate, a lens array arrayed on the second substrate facing the side of the first substrate and corresponding to the location of the image sensing module configured for focusing the an image light on the image sensing module, and an active switch array module disposed on the second substrate facing the side of the first substrate; wherein the image sensing module is configured for receiving the image light focused by the lens array and adjusting the focus of the image sensing module.

### FIELD OF THE INVENTION

The present invention relates to a display panel and a display apparatus using the same, and more particularly to a display panel and a display apparatus using the same not limited by the depth of field and having variable focus.

### BACKGROUND OF THE INVENTION

Depth of Field refers to the range of appearance of image sharpness in focusing by the image sensing device. In the optical, especially the video or photography, the depth of field is a description of distance for the object having sharp focus in the space. General lens can only focus the light to a fixed distance and away from this distance the sharpness is gradual decrease, but the unsharpness is imperceptible under certain distance, i.e. so called the depth of field. To eliminate the limitations of the depth of field, the image sensing component requires a variable focus function.

In the present LCD display panel manufacturing industry, the image sensing module and display panel were combined to form a multi-function display to achieve both the purpose of image scanning and displaying. The image scanning functions such as computer cameras and computer eyes. The multi-function display used as video input devices are widely used in video conferencing, telemedicine, real-time monitoring and so on. In recent years, the network speed continuously increasing accompanied with the development of Internet technology and the techniques of the component using in sensing the object into the image is mature and widely used in the manufacture of the multi-function display, therefore the two ends can communicate with each other with image, video, voice conversation and communication through the video input devices in the network. Furthermore, the multi-function display play an increasingly important role in people's lives and work since it can also be used for processing the current various popular digital imaging, audio and video. However, the image sensing module used in the multi-function display has a fixed focal length range, so its imaging sharpness is limited by the depth of field and with poor performance.

In addition, the traditional glass or plastic lens is only a single focal length, and no variable focusing function. It would be desirable to provide zoom lenses with variable focusing as the name implies more than two traditional lens combination and employs a voice coil motor (VCM) or piezoelectric actuator to change the relative distances between the zoom lenses to obtain variation and magnification of focusing. However, for the traditional autofocus zoom lenses module the volume of the voice coil motor been a trouble in oversize and resulting the difficulties in application.

### SUMMARY OF THE INVENTION

In order to solve the aforementioned problem, it is an object of the present invention to provide a display panel and its applications, and more particularly to a display panel and its applications not limited by the depth of field and have variable focusing to meet the requirements of thin and light in present various devices and raising the usability.

For solving aforementioned technical problem, the present invention utilizes an image sensing module having variable focus combined with a lens array and simultaneously applied to the thin film transistor liquid crystal display (TFT LCD), Base on the imaging principle of lens, the combination of the image sensing module and the TFT panel it can make the object imaging or image scanning free from the limitation of the depth of field and having variable focus to overcome the exiting technical problem. The lens array adopted in the present invention is fabricating by a wafer level technique therefore avoid the problem in volume but convenient for the small and portable product application.

The purpose of the present invention and the technical problem to be solved can be further realized by the following technical embodiments.

It is an object of the present invention to provide a display panel, comprising a first substrate, a second substrate a liquid crystal layer disposed between the first substrate and the second substrate, an image sensing module disposed on the second substrate facing to a side of the first substrate, a lens array arrayed on the second substrate facing the side of the first substrate and corresponding to the location of the image sensing module and configured for focusing an image light on the image sensing module, and an active switch array module disposed on the second substrate facing the side of the first substrate and configured for driving a plurality of liquid crystal molecules distributed in the liquid crystal layer. Wherein, the image sensing module is configured to receive the image light focused by the lens array and adjust the focus of the image sensing module.

In one embodiment of the present invention, the image sensing module is arranged in parallel with the active switch array module.

In one embodiment of the present invention, the image sensing module includes an optical sensor, the optical sensor is a photodiode or a phototransistor.

In one embodiment of the present invention, a material of the optical sensor has energy band gap less than 1.12 eV, and the materials maybe a narrow bandgap organic or a narrow bandgap inorganic.

In one embodiment of the present invention, the energy band gap of the optical sensor material is less than 1.12 eV, and the materials maybe a narrow bandgap of amorphous silicon, microcrystalline silicon, polysilicon or mercury cadmium telluride semiconductor materials.

In one embodiment of the present invention, the lens array is fabricating by a wafer level technique.

In one embodiment of the present invention, the lens array is composed of a material selected from optical grade glass, polymethylmethacrylate or polycarbonate resin.

In one embodiment of the present invention, a light shielding region is disposed between the first substrate and the lens array composing of a material for blocking visible light but transmitting an infrared light.

The purpose of the present invention and the technical problem to be solved can be further realized by the following technical embodiments.

Another object of the present invention is to provide an image sensing display apparatus comprising a direct type or an edge type backlight module, a controller and a display panel. The display panel comprises a first substrate, a second substrate, a liquid crystal layer disposed between the first substrate and the second substrate, an image sensing module disposed on the second substrate facing to a side of the first substrate, a lens array arrayed on the second substrate facing the side of the first substrate and corresponding to the location of the image sensing module configured for focusing an image light on the image sensing module, and an active switch array module disposed on the second substrate facing to the side of the first substrate and configured for driving a plurality of liquid crystal molecules distributed in the liquid crystal layer. Wherein the image sensing module is configured to receive the image light focused by the lens array and adjust the focus of the image sensing module.

In one embodiment of the present invention, the image sensing module is arranged in parallel with the active switch array module.

In one embodiment of the present invention, the image sensing module includes an optical sensor.

In one embodiment of the present invention, the optical sensor is a photodiode or a phototransistor.

In one embodiment of the present invention, the energy band gap of the optical sensor material is less than 1.12 eV, and the materials maybe a narrow bandgap organic or a narrow bandgap inorganic.

In one embodiment of the present invention, the lens array is fabricating by a wafer level technique

In one embodiment of the present invention, the material of the lens array is an optical grade glass.

In one embodiment of the present invention, the material of the lens array is polymethylmethacrylate.

In one embodiment of the present invention, the material of the lens array is polycarbonate resin.

In one embodiment of the present invention, a light shielding region is disposed between the first substrate and the lens array configured for transmitting an infrared light.

The present invention provide another display panel comprises a first substrate, a second substrate, a liquid crystal layer disposed between the first substrate and the second substrate, an image sensing module disposed on the second substrate facing to a side of the first substrate and includes an optical sensor, a lens array arrayed on the first substrate facing the side of the second substrate and corresponding to the location of the image sensing module and configured for focusing the an image light on the image sensing module, the lens array fabricated by a wafer level technique and composed of optical grade material, and an active switch array module disposed on the second substrate facing to the side of the first substrate and in parallel with the image sensing module. Wherein a light shielding region is disposed between the first substrate and the lens array configured for transmitting an infrared light, the image sensing module is configured to receive the image light focused by the lens array and adjust the focus of the image sensing module.

After the improvement of the present invention, the present invention utilizes the lens array inside the TFT liquid crystal display combined with the image sensing module to realize the variable focus, it is not limited by the depth of field and effectively overcome the aforementioned problems in the related application. Furthermore, this combining device can be used to realize the function of image recognition and vein sensing.

Various other objects, advantages and features of the present invention will become readily apparent from the ensuing detailed description, and the novel features will be particularly pointed out in the appended claims.

### BRIEF DESCRIPTION OF FIGURES

The following detailed descriptions, given by way of example, and not intended to limit the present invention solely thereto, will be best be understood in conjunction with the accompanying figures:

FIG. 1A is a schematic view of a display panel having a variable focus according to an embodiment of the present application;

FIG. 1B is a schematic diagram of converting an image light sensing into an electrical signal according to an embodiment of the present invention;

FIG. 1C is a schematic diagram of converting image light sensing into an electrical signal according to another embodiment of the present invention;

FIG. 2A is a schematic view of a display panel having a variable focus according to an embodiment of the present application;

FIG. 2B is a schematic diagram of converting an image light sensing into an electrical signal according to an embodiment of the present invention;

FIG. 2C is a schematic diagram of converting image light sensing into an electrical signal according to another embodiment of the present invention;

FIG. 3A is a schematic view of a display panel having a variable focus according to an embodiment of the present application;

FIG. 3B is a schematic diagram of converting an image light sensing into an electrical signal according to an embodiment of the present invention: and

FIG. 3C is a schematic diagram of converting image light sensing into an electrical signal according to another embodiment of the present invention.

### DETAILED DESCRIPTION OF THE EMBODIMENTS

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

The drawings and description are to be regarded as illustrative in nature and not restrictive. Like reference numerals designate like elements throughout the specification. In addition, the size and thickness of each component shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, the thicknesses of some layers and areas are exaggerated. It will be understood that, when an element such as a layer, film, region, or substrate is referred to as being on another element, it can be directly on the other element or intervening elements may also be present.

Furthermore, in the specification, implies being positioned above or below a target element and does not imply being necessarily positioned on the top on the basis of a gravity direction.

For further explaining the technical means and efficacy of the present application, the display panel and its applications including the embodiments, structures, features and effects thereof according to the present invention will be apparent from the following detailed description and accompanying drawings.

The main principle of the Liquid Crystal Display (LCD) is an electric field employ to the liquid crystal for displaying the numbers or images, wherein the liquid crystal consists of a substance between the liquid and the solid. The image is formed by controlling the light transmission of the liquid crystal display, panel, wherein the liquid crystal is uniformly disposed in the liquid crystal display panel.

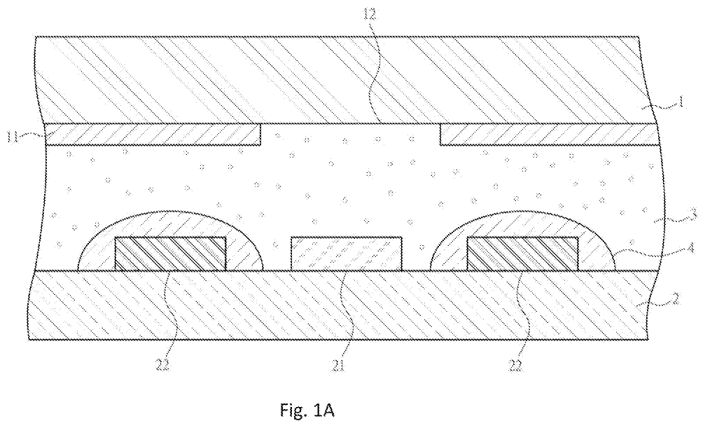

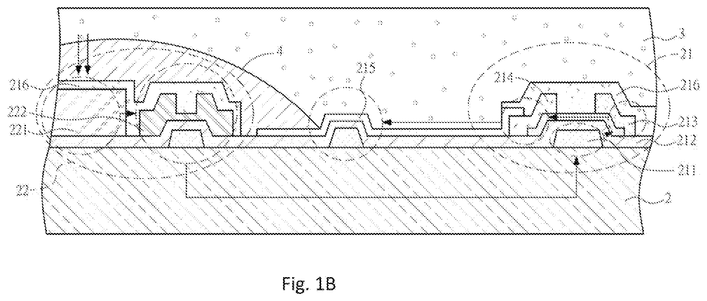

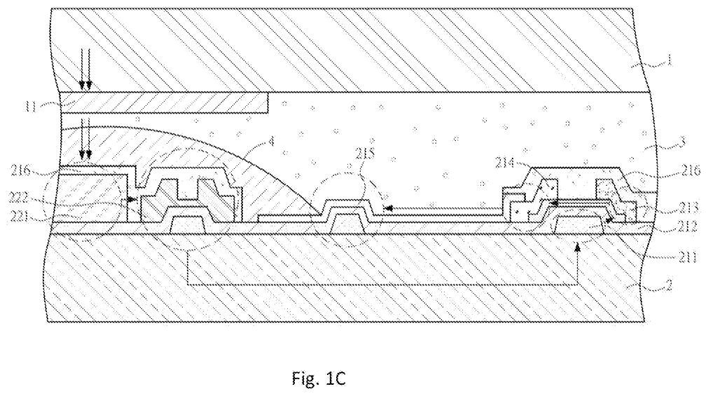

FIG. 1A is a schematic view of a display panel having a variable focus according to an embodiment of the present application. Referring to FIG. 1A; in an embodiment of the present application, the display panel comprises a first substrate 1, a second substrate 2, a liquid crystal layer 3 disposed between the first substrate 1 and the second substrate 2, an image sensing module 22 disposed on the second substrate 2 facing to a side of the first substrate 1, a lens array 4 arrayed on the second substrate 2 facing the side of the first substrate 1 and corresponding to the location of the image sensing module 22 configured for focusing the an image light on the image sensing module 22, and an active switch array module 21 disposed on the second substrate 2 facing to the side of the first substrate 1 configured for driving the liquid crystal molecules 31 distributed uniformity in the liquid crystal layer 3. Wherein the image sensing module 22 is configured for receiving the image light focused by the lens array 4.

In an embodiment of the present invention, a light shielding region 11 is further disposed between the first substrate 1 and the lens array 4 as shown in FIG. 1A. The light shielding region 11 is composed of a material for blocking visible light but transmitting an infrared light.

As shown in FIG. 1A, the display panel comprises a first substrate 1, a second substrate 2, a lens array 4, an active switch array module 21 and an image sensing module 22. For ease of explanation, single active switch array module 21 and single image sensing module 22 are shown in FIG. 1A. This is not limited to the active switch array module 21 and an image sensing module can only individually have a single component. Wherein the first substrate 1 is color filter substrate, the second substrate 2 is TFT substrate, and a liquid crystal layer 3 is sandwiched in the first substrate 1 and the second substrate 2.

In the aforementioned embodiment, the image sensing module 22 is disposed in parallel with the active switch array module 21. The lens array 4 is disposed in the second substrate 2 facing to a side of the first substrate 1 and corresponding to the location of the image sensing module 22, and it can focus the image light on the image sensing module 22 through the lens refraction effect of the lens array.

Furthermore, on central region of a side of the first substrate 1 facing to the second substrate 2 there is a transmitting region 12 for displaying an image and further included a light shielding region 11 arranged in both side of the transmitting region 12. The material used in the light shielding region 11 only allows a specific band of light wavelength to transmit, such as infrared light. For example, in one exemplary embodiment, a light shielding region 11 is disposed between the first substrate 1 and the lens array 4, and the material of the light shielding region 11 is used to effectively block the visible light but allowing only infrared light passing through.

In one of the aforementioned problem to be solved is the individual optical component has only single focal length, so that the sharpness of the image of the object is limited by the depth of field. In order to overcome this drawback, the present invention utilizes a lens array 4 arrayed on the second substrate 2 corresponding to the location of the light shielding region 11 and further combined with the image sensing module 22 locating under the lens array 4 to form a variable focusing image sensing unit, so that to improve the image quality and not limited by the depth of field. In addition, in practice, the circuitry can also be formed on the array substrate to realize the image sensing module 22, even CPU, RAM, Flash, DSP, compression coding processor and imaging sensor. It is to be noted that when a circuit for realizing the above-described function is directly formed on the second substrate, it is possible to synchronize it with the array substrate of the liquid crystal panel by the photolithography process such as exposure with the mask and developing. Wherein the second substrate may be, but is not limited to, a monocrystalline substrate, a low temperature polysilicon substrate, a high temperature polysilicon substrate, or other substrate capable of satisfying a high mobility of the peripheral integrated circuit.

The lens array 4 of the present invention is fabricated by a wafer level technique, having advantage in small volume and no impact on volume consideration in the overall system. The material for lens array 4 is selected from optical grade transparent materials. That is, in an embodiment, the lens array 4 is fabricated by a wafer level technique, and composed of a material selected from optical grade glass, polymethylmethacrylate or polycarbonate resin.

Additionally, another object of the present invention is to provide an image sensing display apparatus. The image sensing display apparatus is combined with the aforementioned panel and backlight module, for example, including: a direct type or an edge type backlight module, and one of the aforementioned image sensing display panels.

Further referring to FIG. 1B FIG. 1B is a schematic diagram of converting an image light sensing into an electrical signal according to an embodiment of the present invention. The image sensing display panel structure shown in the FIG. 1B includes a second substrate 2, and an active switch array module 21 and an image sensing module 22 disposed thereon. The image sensing module 22 is disposed on the side of the second substrate facing to the first substrate 1, the image sensing module 22 has an optical sensor 221 capable of receiving the image light after focusing by the lens array 4 and converting it into a current. Then, the current flowing to the side of the photoelectric switch 222 to form an electrical signal and transmits it to the active switch array module 21 to control the liquid crystal layer 3 to generate an image. The active switch array module 21 has a gate switch 211 to receive an electrical signal transmitted by the photoelectric switch 221, therefore controlling the current of liquid crystal driving voltage flows from the source electrode 213 to the drain electrode 214 and then transferring to the pixel electrode 215 and the first substrate 1 shown in FIG. 1A to form an electric field to control the rotation of the liquid crystal molecules 31 in the liquid crystal layer 3. In the meanwhile, an electrically insulating protective layer 212 is disposed on the gate switch 211, and also a protective layer 216 is disposed above the active switch array module 21 and the image sensing module 22 to isolate the liquid crystal molecules.

In this embodiment, the image sensing module 22 includes an optical sensor 221, the optical sensor 221 may be the photodiode or phototransistor, the material of optical sensor may be selected from a narrow bandgap organic and inorganic materials and the energy band gap of the material is less than 1.12 eV, such as phototube composed of amorphous silicon, microcrystalline silicon, polysilicon or mercury cadmium telluride (HgCdTe) semiconductor materials.

Referring to FIG. 1C, FIG. 1C is a schematic diagram of converting image light sensing into an electrical signal according to another embodiment of the present invention. In the embodiment as shown in FIG. 1C, the first substrate 1 of the image sensing display panel includes a transmitting region 12 as shown in FIG. 1A and a light shielding region 11 allowing only specific light wavelength passing through.

The image sensing display panel structure shown in the FIG. 1C includes a first substrate 1 having a transmitting region 12 (as shown in FIG. 1A) and a light shielding region 11 allowing only infrared light passing through, and a second substrate 2 having an active switch array module 21 and an image sensing module 22 disposed thereon (as shown in FIG. 1B). The image sensing module 22 is disposed on the second substrate 2 facing to the first substrate 1 and corresponding to the location under the light shielding region 11. The image sensing module 22 has an optical sensor 221 capable of receiving an infrared light derived from the ambient visible light transmitting through the light shielding region 11, and then transforming into the current. Then, the current flowing to the side of the photoelectric switch 222 to form an electrical signal and transmits it to the active switch array module 21 (as shown in FIG. 1B) to control the liquid crystal layer 3 to generate an image.

In above embodiments, the optical sensor 221 may be a photodiode or a phototransistor, the material of optical sensor 221 may be selected from a narrow bandgap organic and inorganic materials and the energy band gap of the material is less than 1.12 eV, such as phototube composed of amorphous silicon, microcrystalline silicon, polysilicon or mercury cadmium telluride (HgCdTe) semiconductor materials. Since the optical sensor 221 of the present embodiment mainly absorbs the infrared light to induce the current, therefore a light shielding region allowing, only infrared light passing through is disposed in this embodiment as shown in the FIG. 1A. Based on the arrangement of the light shielding region 11, the image light to be received by the image sensing module 22 it can passing through light shielding region 11 and then focusing by the lens array 4 and free from the external ambient light or backlight interference, so that the sensitivity of the image sensing module 22 will not be affected.

Therefore as shown in FIG. 1C, in the aforementioned embodiment, the active switch array module 21 has a gate switch 211 to receive an electrical signal transmitted from the photoelectric switch 221 it transforming the received infrared light, therefore controlling the current of liquid crystal driving voltage flows from the source electrode 213 to the drain electrode 214 and then transferring to the pixel electrode 215 and the first substrate 1 shown in FIG. 1A to form an electric field to control the rotation of the liquid crystal molecules 31 in the liquid crystal layer 3. In the meanwhile, an electrically insulating protective layer 212 is disposed above the gate switch 211, and also a protective layer 216 is disposed above the active switch array module 21 and the image sensing module 22 to isolate the liquid crystal molecules.

The present invention utilizes the lens array inside the TFT liquid crystal display combined with the image sensing module to realize the variable focus, it is not limited by the depth of field and effectively overcome the aforementioned problems in the related application. Furthermore, this combining device can be used to realize the function of image recognition and vein sensing.

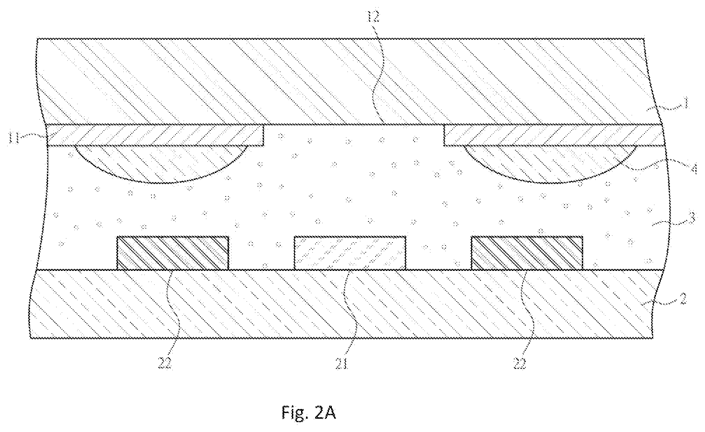

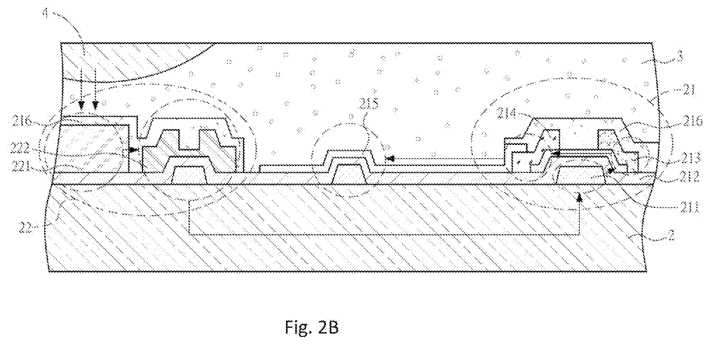

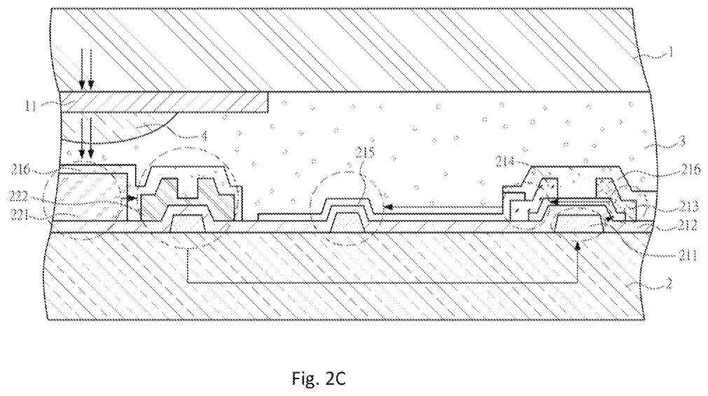

Through the combination of the lens module and the image sensing module to achieve the function of variable focus can be as shown in the FIGS. 2A, 2B and 2C, the lens module 4 is disposed on a side of the first substrate 1 facing to the second substrate 2 and corresponding to the location of the image sensing, module 22, the image light been focused by the lens module 4 and imaged on the image sensing module 22. As shown in FIG. 2B, the image sensing module 22 has an optical sensor 221 capable of receiving the image light been focused by the lens module 4 and transforming it into the current. Then, the current flowing to the side of the photoelectric switch 222 to form an electrical signal and transmits it to the active switch array module 21 to control the liquid crystal layer 3 to generate an image. The active switch array module 21 has a gate switch 211 to receive an electrical signal transmitted by the photoelectric switch 221, therefore controlling the current of liquid crystal driving voltage flows from the source electrode 213 to the drain electrode 214 and then transferring to the pixel electrode 215 and the first substrate 1 shown in FIG. 2A to form an electric field to control the rotation of the liquid crystal molecules 31 in the liquid crystal layer 3. In the meanwhile, an electrically insulating protective layer 212 is disposed above the gate switch 211, and also a protective layer 216 is disposed above the active switch array module 21 and the image sensing module 22 to isolate the liquid crystal molecules. As shown in FIG. 2C, a light shielding region 11 is disposed between the first substrate 1 and the lens module 4 to screen and isolate the specific light wavelength.

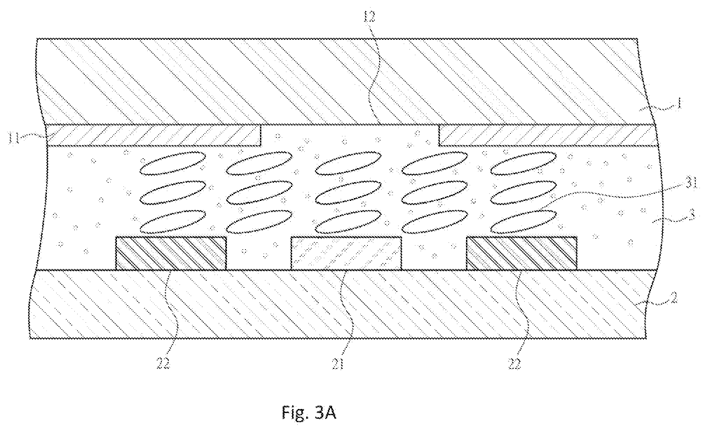

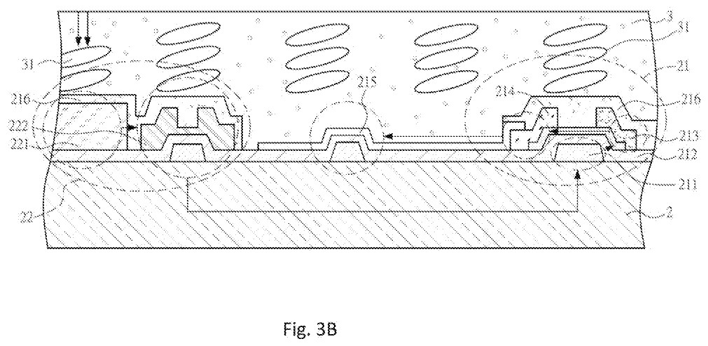

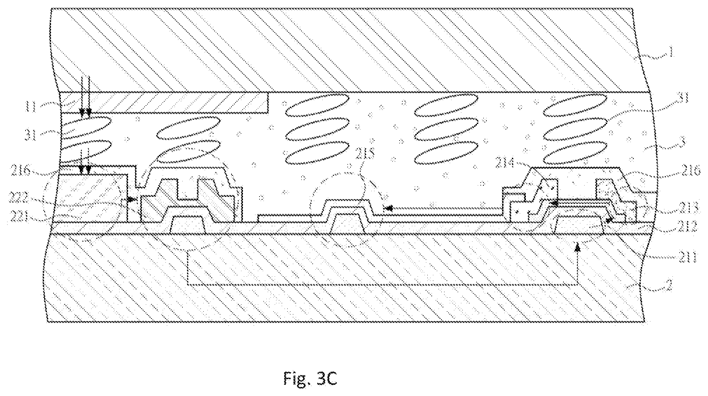

Or it can be an embodiment as shown in the FIGS. 3A, 3B and 3C, according to the property of each liquid crystal molecules having the shape with thick in middle and thin in two ends, by tilting the liquid crystal molecules in response to the electric field to realize the function of variable focusing. In this embodiment, the structure of the display panel without lens array 4 as shown in FIGS. 1A and 2A, and by adjusting the electric field to tilt the liquid crystal molecules 31 in the liquid crystal layer 3 to focus the image light on the image sensing module 22. In practice, the liquid crystal molecules 31 can be filled between the first substrate 1 (the color film substrate) and the second substrate 2 (the active switch array substrate) by the TFT-lXD (thin film transistor liquid crystal display) technology to form to “flat type” liquid crystal lens. It utilizes the properties of the liquid crystal molecules in its birefringence and tilting with the electric field to make the light focusing or diverging to resemble the optical effect similar to the lens (plastic or glass lens).

As shown in FIG. 3B, the image sensing module 22 an optical sensor 221 capable of receiving the image light after focusing by the liquid crystal molecules 31 and converting it into a current. Then, the current flowing to the side of the photoelectric switch 222 to form an electrical signal and transmits it to the active switch array module 21 to control the liquid crystal layer 3 to generate an image. The active switch array module 21 has a gate switch 211 to receive an electrical signal transmitted by the photoelectric switch 221, therefore controlling the current of liquid crystal driving voltage flows from the source electrode 213 to the drain electrode 214 and then transferring to the pixel electrode 215 and the first substrate 1 shown in FIG. 3A to form an electric field to control the rotation of the liquid crystal molecules 31 in the liquid crystal layer 3. In the meanwhile, an electrically insulating protective layer 212 is disposed on the gate switch 211, and also a protective layer 216 is disposed above the active switch array module 21 and the image sensing module 22 to isolate the liquid crystal molecules.

As shown in FIG. 3C, a light shielding region 11 is disposed between the first substrate 1 and the lens module 4 to screen and isolate the specific light wavelength. Comparing with the present lens, the liquid crystal lens has the following advantages: 1. Only the digital technology to be employing in the present lens to enlarge portion of the photo to realize “zoom” visual effects therefore it can not realize the real optical zoom, however the liquid crystal lens can be by applying different voltages to change the orientation of the liquid crystal molecules to achieve the effect on physical variable focus, it can achieve optical zoom result effectively in a small space and the feature in light and thin is a major advantage. 2. The present lenses have obvious outward appearance and it is detrimental protection of confidential information, however the “flat type” liquid crystal lens employing the properties of the liquid crystal molecules has no difference in the exterior comparing with the liquid crystal panel and has strong obscuration.

Referring to the FIGS. 1A, 1B 1C 2A, 2B, 2C, 3A, 3B, and 3C, in an embodiment, a display apparatus includes a direct type or an edge type backlight module, a controller, and further includes display panel described in the respective embodiments. Wherein, the display apparatus may employ the liquid crystal display panel selected from the following modes: Twisted Nematic (TN), Super Twisted Nematic (STN), Optically Compensated Birefringence (OCB), Vertical Alignment (VA), curved, but not limited thereto. In the embodiments of the present invention, the relevant lens is formed on or attached to the substrate of the display panel (e.g., a lens module) or distributed on an inner liquid crystal layer (e.g., a liquid crystal lens), there is no need to occupy the peripheral area of the display panel, simultaneously, the display apparatus has stronger image capture capability due to equip the “flat” lens with physical variable focus.

In addition, in the specification, unless explicitly described to the contrary, the word “comprise” and variations such as “comprises” or “comprising” will be understood to imply the inclusion of stated elements but not the exclusion of any other elements.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A display panel, comprising:
a first substrate;
a second substrate;
a liquid crystal layer, disposed between the first substrate and the second substrate;
an image sensing module, disposed on the second substrate facing a side of the first substrate;
a lens array, arrayed on the second substrate facing the side of the first substrate and corresponding to the location of the image sensing module, and configured for focusing an image light on the image sensing module; and
an active switch array module, disposed on the second substrate facing the side of the first substrate;
wherein the image sensing module is configured to receive the image light focused by the lens array and adjust the focus of the image sensing module.

2. The display panel according to claim 1, wherein the image sensing module is arranged in parallel with the active switch array module.

3. The display panel according to claim 1, wherein the image sensing module comprises an optical sensor.

4. The display panel according to claim 3, wherein the optical sensor is photodiode.

5. The display panel according to claim 3, wherein the optical sensor is phototransistor.

6. The display panel according to claim 3, wherein the optical sensor comprises a material selected from a narrow bandgap organic and inorganic materials, and the energy band gap of the material is less than 1.12 eV.

7. The display panel according to claim 1, wherein the lens array is fabricated by a wafer level technique.

8. The display panel according to claim 7, wherein the lens array comprises a material selected from optical grade glass, polymethylmethacrylate or polycarbonate resin.

9. The display panel according to claim 1, wherein a light shielding region is disposed between the first substrate and the lens array, and configured for transmitting an infrared light.

10. A display apparatus comprises a backlight module, a controller and a display panel, the display panel comprising:
a first substrate;
a second substrate;
a liquid crystal layer, disposed between the first substrate and the second substrate;
an image sensing module, disposed on the second substrate facing a side of the first substrate;
a lens array, arrayed on the second substrate facing to the side of the first substrate and corresponding to the location of the image sensing module, and configured for focusing the image light on the image sensing module; and
an active switch array module, disposed on the second substrate facing the side of the first substrate;
wherein, the image sensing module is configured to receive the image light focused by the lens array and adjust the focus of the image sensing module.

11. The display apparatus according to claim 10, wherein the image sensing module is arranged in parallel with the active switch array module.

12. The display apparatus according to claim 10, wherein the image sensing module comprises an optical sensor.

13. The display apparatus according to claim 12, wherein the optical sensor is a photodiode or a phototransistor.

14. The display apparatus according to claim 12, wherein the optical sensor comprises a material selected from a narrow bandgap organic and inorganic materials, and the energy band gap of the material is less than 1.12 eV.

15. The display apparatus according to claim 10, wherein the lens array is fabricated by a wafer level technique.

16. The display apparatus according to claim 15, wherein the material of the lens array is an optical grade glass.

17. The display apparatus according to claim 15, wherein the material of the lens array is polymethylmethacrylate.

18. The display apparatus according to claim 15, wherein the material of the lens array is polycarbonate resin.

19. The display apparatus according to claim 10, wherein a light shielding region is disposed between the first substrate and the lens array, and configured for transmitting an infrared light.

20. A display panel, comprising:
a first substrate;
a second substrate;
a liquid crystal layer, disposed between the first substrate and the second substrate;
an image sensing module, disposed on the second substrate facing a side of the first substrate, having an optical sensor;
a lens array, arrayed on the first substrate facing the side of the second substrate and corresponding to the location of the image sensing module, and configured for focusing the image light on the image sensing module, the lens array fabricated by a wafer level technique and composed of an optical grade material; and
an active switch array module, disposed on the second substrate facing the side of the first substrate and in parallel with the image sensing module;
wherein, a light shielding region is disposed between the first substrate and the lens array and is configured for transmitting an infrared light, and the image sensing module is configured to receive the image light focused by the lens array and adjust the focus of the image sensing module.
